(19) United States
(12) Patent Application Publication
(10) Pub. No.: US 2024/0021418 A1
(43) Pub. Date: Jan. 18, 2024

(54) APPARATUS FOR TREATING SUBSTRATE

(71) Applicant: PSK INC., Hwaseong-si (KR)

(72) Inventors: Kwang Sung YOO, Hwaseong-si (KR); Tae Hwan YOUN, Hwaseong-si (KR); Hyeon Won JUNG, Hwaseong-si (KR)

(73) Assignee: PSK INC., Hwaseong-si (KR)

(21) Appl. No.: 18/352,506

(22) Filed: Jul. 14, 2023

(30) Foreign Application Priority Data
Jul. 18, 2022 (KR) 10-2022-0088487

(51) Int. Cl. H01J 37/32

(52) U.S. Cl. CPC H01J 37/32724; H01J 37/32642; H01J 37/3244; H01J 37/32568; H01J 37/32541; H01J 2237/334

(57) ABSTRACT

The inventive concept provides a substrate treating apparatus. The substrate treating apparatus includes a housing having a treating space; a support unit configured to support a substate within the treating space; and a plasma source for generating a plasma by exciting a gas supplied to the treating space, and wherein the support unit includes: a chuck having the substrate mounted to a top surface thereof; and a ring member in a ring shape surrounding an outer side of the chuck, and the ring member includes a cut surface which divides the ring member and a holding member positioned at the cut surface which holds a position of the ring member which is divided by the cut surface.

### CROSS-REFERENCE TO RELATED APPLICATIONS

A claim for priority under 35 U.S.C. § 119 is made to Korean Patent Application No. 10-2022-0088487 filed on Jul. 18, 2022, in the Korean Intellectual Property Office, the entire contents of which are hereby incorporated by reference.

### BACKGROUND

Embodiments of the inventive concept described herein relate to a substrate treating apparatus, more specifically, an apparatus for treating a substrate using a plasma.

A plasma refers to an ionized gas state consisting of ions, radicals, and electrons. The plasma is produced by a very high temperature, a strong electric field, or a high-frequency electromagnetic field. A semiconductor element manufacturing process includes an etching process or an ashing process of removing a thin film on a substrate using a plasma. The ashing process or the etching process is performed by colliding or reacting ion particles and radical particles contained in the plasma with a film on the substrate.

When the substrate is treated using the plasma, a high-temperature atmosphere is created in a region at which the plasma is generated. Accordingly, members positioned adjacent to the region at which plasma is generated are thermally expanded. In order to precisely generate the plasma in a region required by a process, a center of a chuck supporting the substrate and a center of an insulation ring surrounding an outer circumferential surface of the chuck must match. In order to align the center of the chuck and the center of the insulation ring, they should be positioned within a tolerance between both members. In this case, if the plasma is generated to treat the substrate, the chuck and the insulation ring expand thermally, respectively, due to the high-temperature atmosphere created in a plasma generation region. Particularly, if the chuck thermally expands and its volume increases, damages occur on the insulation ring, and ultimately, scratches are generated on a surface of the insulation ring or the insulation ring is damaged. Even if a fine damage occurs on the insulation ring, a uniformity of the plasma is reduced, and thus a uniform plasma treatment on the substrate is not possible.

When the chuck and the insulation ring are disposed with certain tolerance to prevent a damage to the above-described insulation ring, it is difficult to match the centers of the chuck and the insulation ring with each other. If the centers of the chuck and the insulation ring do not match, the chuck and the insulation ring inevitably have an asymmetrical structure, and thus it is difficult to precisely generate the plasma in a region required in the process. In particular, in the case of a so-called Bevel Etch process which generates the plasma only in an edge region of the substrate, it is difficult to generate the plasma suitable for process requirements if the center of the chuck and the insulation ring do not match. To solve this problem, it is possible to consider fixing a position of the insulation ring while placing a tolerance between the chuck and the insulation ring, but this causes a problem of increasing a structural complexity of the apparatus.

### SUMMARY

Embodiments of the inventive concept provide a substrate treating apparatus for uniformly treating a substrate.

Embodiments of the inventive concept provide a substrate treating apparatus for generating a uniform plasma at an edge region of a substrate.

Embodiments of the inventive concept provide a substrate treating apparatus for matching a center of a chuck supporting a substrate and a center of a ring member surrounding the chuck.

Embodiments of the inventive concept provide a substrate treating apparatus for minimizing a damage of a ring member at a high temperature atmosphere.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a housing having a treating space; a support unit configured to support a substate within the treating space; and a plasma source for generating a plasma by exciting a gas supplied to the treating space, and wherein the support unit includes: a chuck having the substrate mounted to a top surface thereof; and a ring member in a ring shape surrounding an outer side of the chuck, and the ring member includes a cut surface which divides the ring member and a holding member positioned at the cut surface which holds a position of the ring member which is divided by the cut surface.

In an embodiment, a groove at which the holding member is inserted is formed at the ring member.

In an embodiment, the groove is formed at an inner side of the ring member, and a top end of the groove is positioned lower than a top end of the ring member, and a bottom end of the groove is positioned higher than a bottom end of the ring member.

In an embodiment, the ring member is divided with respect to the cut surface, and the holding member is inserted in the groove to limit a movement in a lengthwise direction of each divided ring member.

In an embodiment, the cut surface is formed in a horizontal direction to the cut surface of the ring member.

In an embodiment, at the ring member, a plurality of cut surfaces are formed along a circumferential direction of the ring member, and a plurality of holding members are each positioned at each of the plurality of cut surfaces.

In an embodiment, the substrate treating apparatus further includes: a dielectric plate positioned to face a top surface of the substrate supported on the support unit; and a gas supply unit configured to supply a gas to an edge region of the substrate, and wherein the plasma source includes: a top edge electrode positioned above the edge region; and a bottom edge electrode positioned below the edge region.

In an embodiment, the bottom edge electrode is formed in a ring shape, and surrounds an outer side of the ring member.

In an embodiment, the chuck and the ring member share a same center, and an inner side of the ring member contacts the outer side of the chuck.

In an embodiment, the chuck and the ring member have a different thermal expansion rate from one another.

The inventive concept provides a support unit for supporting a substrate. The support unit for supporting a substrate includes a chuck supporting the substrate on a top surface; a ring member in a ring shape surrounding an outer circumference of the chuck; and an edge electrode formed in a ring shape surrounding an outer circumference of the ring member, and which is positioned at an edge region of the substrate supported on the chuck to generate a plasma at the edge region, and wherein the ring member includes a cut surface dividing the ring member and a holding member positioned at the cut surface which holds a position of the ring member which is divided by the cut surface.

In an embodiment, the chuck and the ring member share a same center, and an inner side surface of the ring member contact an outer side of the chuck.

In an embodiment, a thermal expansion rate of the chuck and a thermal expansion rate of the ring member are different from one another.

In an embodiment, the thermal expansion rate of the chuck is higher than the thermal expansion rate of the ring member.

In an embodiment, a groove at which the holding member is inserted is formed at the ring member, the groove is formed at an inner side of the ring member, and a top end of the groove is positioned lower than a top end of the ring member, and a bottom end of the groove is positioned higher than a bottom end of the ring member.

In an embodiment, the ring member is divided with respect to the cut surface, and the holding member is inserted in the groove to limit a movement in a lengthwise direction of each divided ring member.

In an embodiment, at the ring member, a plurality of cut surfaces are formed along a circumferential direction of the ring member, and a plurality of holding members are each positioned at each of the plurality of cut surfaces.

The inventive concept provides a substrate treating apparatus. The substrate treating apparatus includes a housing having a treating space; a support unit configured to support a substate within the treating space; a dielectric plate positioned to face a top surface of a substrate supported on the support unit; a gas supply unit configured to supply a gas to an edge region of the substrate; a top edge electrode positioned above the edge region; and a bottom edge electrode positioned below the edge region, and wherein the support unit includes: a chuck having the substrate mounted to a top surface thereof; and a ring member in a ring shape surrounding an outer side of the chuck, and the ring member includes: a cut surface which divides the ring member; a groove which is formed at a position corresponding to the cut surface; and a holding member inserted in the groove to limit a movement in a lengthwise direction of the ring member which is divided by the cut surface.

In an embodiment, the chuck and the ring member share a same center, and an inner side of the ring member contacts the outer side of the chuck, and the groove is formed at the inner side between a top end of the ring member and a bottom end of the ring member.

In an embodiment, the chuck and the ring member have a different thermal expansion rate from one another.

According to an embodiment of the inventive concept, a substrate may be uniformly treated.

According to an embodiment of the inventive concept, a center of a chuck supporting a substrate and a center of a ring member surrounding the chuck may be matched to generate a uniform plasma at an edge region of the substrate.

According to an embodiment of the inventive concept, a damage of a ring member may be minimized at a high temperature atmosphere.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view schematically illustrating a substrate treating apparatus according to an embodiment of the inventive concept.

FIG. 2 is a view schematically illustrating a process chamber according to an embodiment of FIG. 1.

FIG. 3 is a perspective view illustrating a holding member inserted into a ring member according to an embodiment of FIG. 2.

FIG. 4 is a perspective view illustrating the holding member withdrawn from the ring member according to an embodiment of FIG. 2.

FIG. 5 schematically illustrates the process chamber according to an embodiment of FIG. 2 performing a plasma treatment process.

FIG. 6 is a perspective view schematically illustrating a chuck thermally expanding when the plasma treatment process is performed in the process chamber according to an embodiment of FIG. 2.

FIG. 7 schematically illustrates an enlarged view of a portion A of FIG. 6.

FIG. 8 is a perspective view illustrating the ring member according to another embodiment of FIG. 2.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

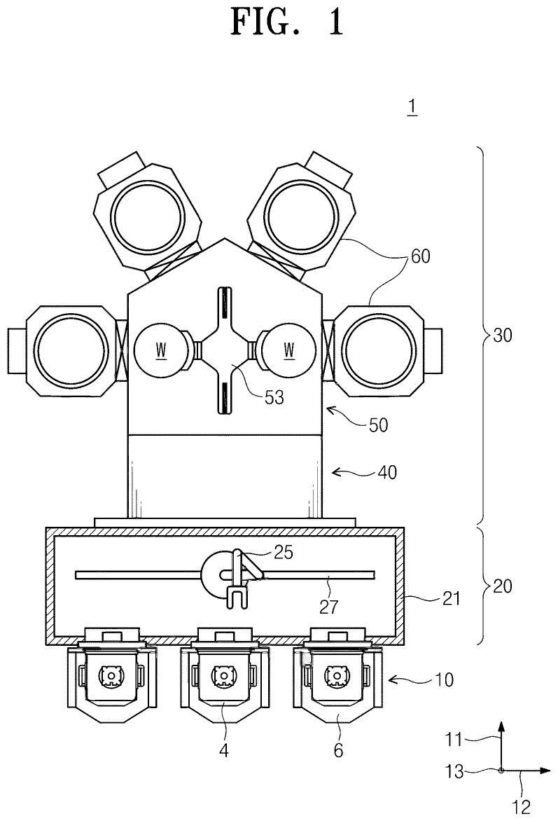

Hereinafter, embodiments of the inventive concept will be described in detail with reference to FIG. 1 to FIG. 8.

FIG. 1 is a view schematically illustrating a substrate treating apparatus according to an embodiment of the inventive concept. Referring to FIG. 1, the substrate treating apparatus 1 has an Equipment Front End Module (EFEM) 20 and a treating module 30. The front end module 20 and the treating module 30 are disposed in a direction.

Hereinafter, a direction in which the front end module 20 and the treating module 30 are disposed is defined as a first direction 11. In addition, when seen from above, a direction perpendicular to the first direction 11 is defined as a second direction 12. In addition, a direction perpendicular to a plane including both the first direction 11 and the second direction 12 is defined as a third direction 13. For example, the third direction 13 may be a direction perpendicular to the ground.

The front end module 20 has a load port 10 and a transfer frame 21. The load port 10 has a plurality of support portions 6. A plurality of support portions 6 may be arranged in a row along the second direction 12. A container 4 may be seated on each support portion 6. The container 4 according to an embodiment may include a cassette, a FOUP, or the like. The container 4 may accommodate a substrate to be used in a process and a substrate on which a process has been completed.

The transfer frame 21 is disposed between the load port 10 and the treating module 30. The transfer frame 21 has an inner space. The inner space of the transfer frame 21 may be maintained in an atmospheric pressure atmosphere. A first transfer robot 25 is disposed inside the transfer frame 21. The first transfer robot 25 may move along the return rail 27 disposed in the second direction 12 to transfer the substrate between the container 4 and the treating module 30.

According to an embodiment, the treating module 30 may perform a treatment process of removing a thin film in an edge region of the substrate by receiving a substrate stored in the container 4 placed in the load port 10. The treating module 30 may include a load lock chamber 40, a transfer chamber 50, and a process chamber 60.

The load lock chamber 40 is disposed adjacent to the front end module 20. For example, the load lock chamber 40 may be disposed between the transfer frame 21 and the transfer chamber 50. The load lock chamber 40 has an inner space at which a substrate to be used in a process stands-by before being transferred to the process chamber 60 or before a substrate on which a process has been completed is transferred to the front end module 20. The inner space of the load lock chamber 40 may be switched between an atmospheric pressure atmosphere and a vacuum pressure atmosphere.

The transfer chamber 50 transfers the substrate. According to an embodiment, the transfer chamber 50 may transfer a substrate between the load lock chamber 40 and the process chamber 60. The transfer chamber 50 is disposed adjacent to the load lock chamber 40. The transfer chamber 50 may have a polygonal body when seen from above. A load lock chamber 40 and a plurality of process chambers 60 may be disposed along the circumference of the body outside the body.

The inside of the transfer chamber 50 may be generally maintained in a vacuum pressure atmosphere. Inside the transfer chamber 50, a second transfer robot 53 is placed between the load lock chamber 40 and the process chamber 60 to transfer the substrate. The second transfer robot 53 may transfer the untreated substrate waiting in the load lock chamber 40 to the process chamber 60, or transfer the substrate that has completed the predetermined process from the process chamber 60 to the load lock chamber 40. In addition, the second transfer robot 53 may transfer the substrate between the plurality of process chambers 60.

The process chamber 60 is disposed adjacent to the transfer chamber 50. A plurality of process chambers 60 may be provided. The plurality of process chambers 60 may be disposed along a circumference of the transfer chamber 50. In each of the process chambers 60, a predetermined process treatment is performed on the substrate. The process chamber 60 can receive the substrate from the second transfer robot 53, perform a predetermined process treatment on the substrate, and hand over a substrate on which the process treatment has been completed to the second transfer robot 53. A process treatment performed in each process chamber 60 may be different from each other.

Hereinafter, a process chamber 60 performing a plasma treatment process among the process chambers 60 will be described as an example. According to an embodiment, the process chamber 60 performing the plasma treatment process may etch or ash a film on the substrate. The film may include various types of films such as a polysilicon film, an oxide film, and a silicon nitride film. Selectively, the film may be a natural oxide film or a chemically produced oxide film. The film may be a foreign substance generated in a process of treating the substrate. /Selectively, the film may be a foreign substance attached to and/or remaining on a top surface and a bottom surface of the substrate.

In addition, the process chamber 60 which performs a plasma treatment process described below may be a chamber configured to perform a Bevel Etch process which removes a film on the edge region of the substrate among the process chambers 60 of the substrate treating apparatus 1. However, it is not limited to this, and the process chamber 60 of the substrate treating apparatus 1 described below can be applied equally or similarly to a chamber which performs various processes for treating the substrate. In addition, the process chamber 60 described below can be applied equally or similarly to various chambers in which the plasma treatment process on the substrate is performed.

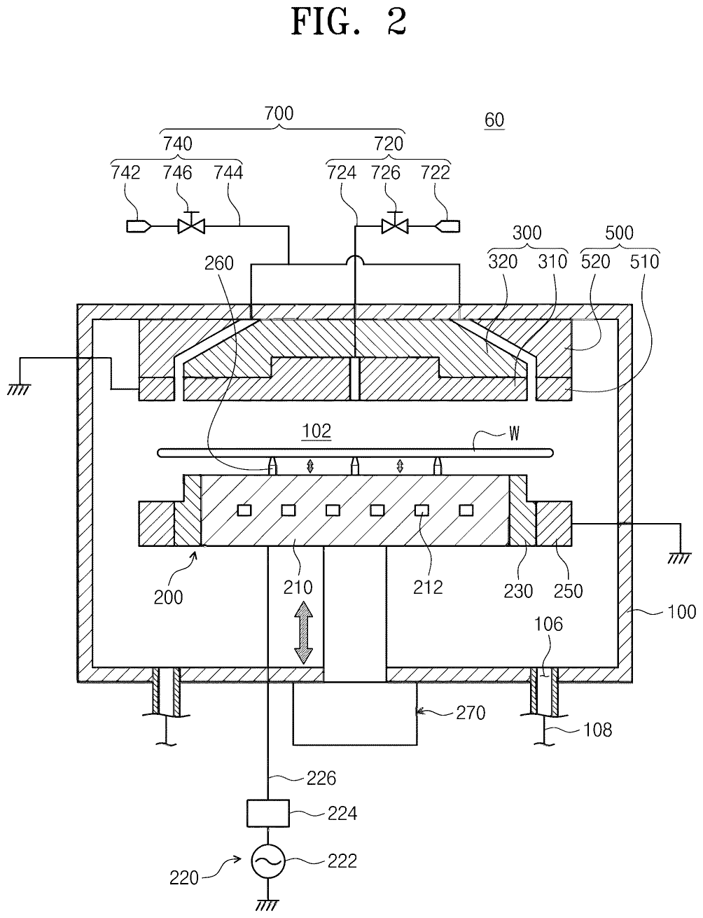

FIG. 2 schematically illustrates a process chamber according to an embodiment of FIG. 1. Referring to FIG. 2, the process chamber 60 according to an embodiment may perform a process of removing a film formed on the substrate W using a plasma. For example, the process chamber 60 can supply a gas and process the edge region of the substrate W using the plasma generated by exciting a supplied gas.

The process chamber 60 may include a housing 100, a support unit 200, a dielectric unit 300, a top electrode unit 500, and a gas supply unit 700.

The housing 100 may be a chamber. According to an embodiment, the housing 100 may be a vacuum chamber. The housing 100 has a treating space 102 therein. The treating space 102 functions as a space in which the substrate W is treated. An opening (not shown) is formed on a sidewall of the housing 100. The substrate W may be taken into the treating space 102 through an opening (not shown) or may be taken out of the treating space 102. Although not shown, the opening (not shown) may be selectively opened and closed by a door assembly (not shown).

An exhaust hole 106 is formed on a bottom surface of the housing 100. The exhaust hole 106 may be connected to an exhaust line 108. The exhaust line 108 may be connected to a depressurizing member (not shown) applying a negative pressure

The support unit 200 is positioned in the treating space 102. The support unit 200 supports the substrate W in the treating space 102. The support unit 200 may include a chuck 210, a power member 220, a ring member 230, a holding member 240, and a bottom edge electrode 250.

The chuck 210 supports the substrate W in the treating space 102. The chuck 210 may have a substantially circular shape when seen from above. According to an embodiment, the top surface of the chuck 210 may have a diameter smaller than that of the substrate W. Accordingly, a center region of the substrate W supported by the chuck 210 is settled on the top surface of the chuck 210, and the edge region of the substrate W may not contact the top surface of the chuck 210. That is, in a state at which the center region of the substrate W is seated on the chuck 210, the edge region of the substrate W may be positioned on an outer region of the chuck 210.

A lift pin 260 may be positioned within the chuck 210. The lift pin 260 may lift and lower the substrate W. In addition, the driving member 270 may be coupled to the chuck 210. The driving member 270 may lift and lower the chuck 210.

A heater 212 may be disposed within the chuck 210. For example, the heater 212 may be buried in the chuck 210. The heater 212 heats the chuck 210. The heater 212 may be electrically connected to a power module not shown. The heater 212 may generate a heat by resisting a current supplied from a power module (not shown). For example, the heater 212 may be a spiral coil. The heat generated by the heater 212 is transferred to the substrate W through the chuck 210. Accordingly, the substrate W seated on the chuck 210 may be maintained at a predetermined temperature by the heat generated by the heater 212.

A cooling fluid channel not shown may be formed within the chuck 210. A cooling fluid may flow within the cooling fluid channel (not shown). The cooling fluid cools the chuck 210 while flowing within the cooling fluid channel (not shown), thereby controlling a temperature of the substrate W supported by the chuck 210. A configuration for cooling the chuck 210 is not limited to a configuration for supplying the cooling fluid, and can be modified into various configurations (e.g., a cooling plate, etc.) capable of cooling the chuck 210.

A material of the chuck 210 may include a metal. For example, the material of the chuck 210 may include an aluminum (Al). In addition, a surface of the chuck 210 may be coated with a material different from the material of the chuck 210. The chuck 210 may thermally expand in a high-temperature atmosphere. For example, the chuck 210 may have a first thermal expansion rate.

The power supply member 220 supplies a power to the chuck 210. The power member 220 may include a power source 222, a matching device 224, and a power line 226. The power source 222 according to an embodiment may be a bias power source. In addition, the power source 222 may be an RF power source. The power source 222 may be connected to the chuck 210 through the power line 226. The matching device 224 may be installed on the power line 226 to perform an impedance matching.

The ring member 230 may have a ring shape. The ring member 230 may be disposed between the chuck 210 and the bottom edge electrode 250 to be described later. The ring member 230 may be disposed along a circumference of the chuck 210. The ring member 230 may be disposed to surround an outer circumferential surface of the chuck 210 when seen from above. For example, an inner circumferential surface of the ring member 230 may be in contact with the outer circumferential surface of the chuck 210. In addition, the ring member 230 may have a center consistent with the center of the chuck 210. According to an embodiment, the ring member 230 may share a center thereof with the chuck 210.

According to an embodiment, the ring member 230 may include an insulating material. The material of the ring member 230 may include a ceramic. The ring member 230 may thermally expand in a high-temperature atmosphere. For example, the ring member 230 may have a second thermal expansion rate. The second thermal expansion rate may be less than the first thermal expansion rate. For example, the second thermal expansion rate may be approximately three times smaller than the first thermal expansion rate. That is, the thermal expansion rate of the ring member 230 may be relatively smaller than the thermal expansion rate of the chuck 210. Accordingly, the above-described chuck 210 may expand relatively more in a high temperature atmosphere than the ring member 230.

According to an embodiment, a top surface of the ring member 230 may be stepped. For example, a top surface of an inner portion of the ring member 230 may have a height higher than that of a top surface of an outer portion. According to an embodiment, the top surface of the inner portion of the ring member 230 may be positioned at a height corresponding to the top surface of the chuck 210. In addition, the top surface of the outer portion of the ring member 230 may be positioned at a height lower than the top surface of the chuck 210. Accordingly, the edge region of the substrate W seated on the top surface of the chuck 210 may be supported on the top surface of the inner portion of the ring member 230. That is, the top surface of the inner portion of the ring member 230 may support a bottom surface of the edge region of the substrate W. However, the inventive concept is not limited thereto, and the top surface of the ring member 230 may be generally flat.

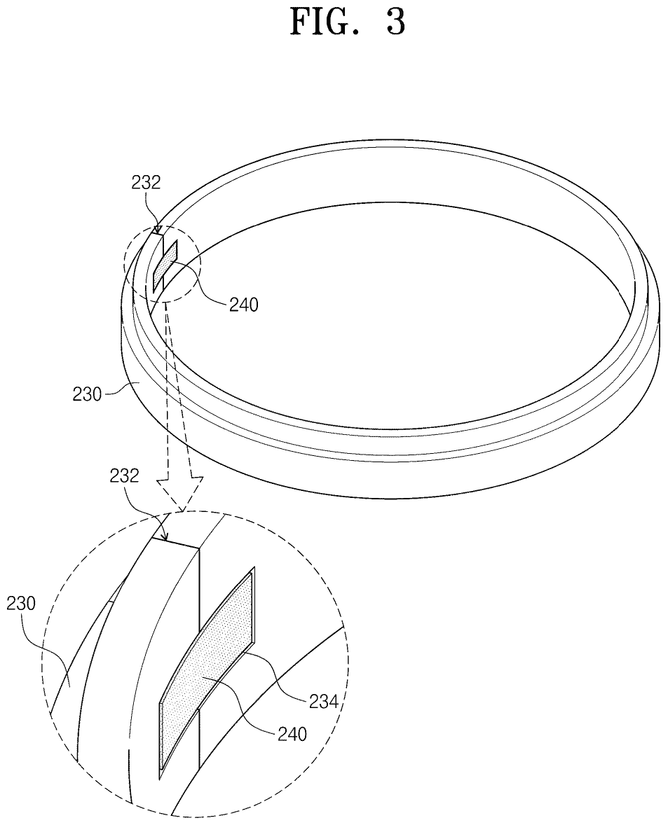

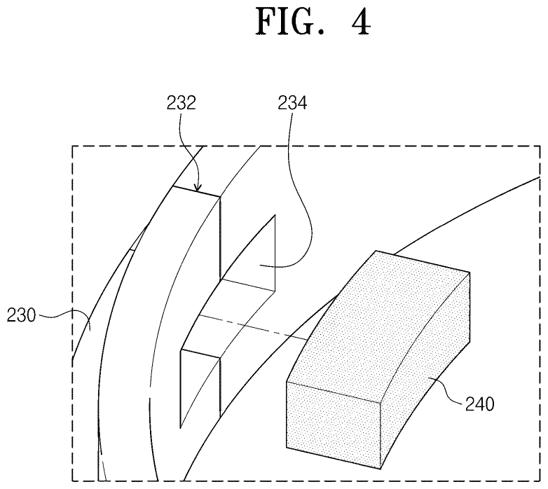

FIG. 3 is a perspective view illustrating a holding member inserted into a ring member according to an embodiment of FIG. 2. FIG. 4 is a perspective view illustrating the holding member withdrawn from the ring member according to an embodiment of FIG. 2.

Hereinafter, the ring member and the holding member inserted into the ring member according to an embodiment of the inventive concept will be described in detail with reference to FIG. 2 to FIG. 4.

The ring member 230 may include a cut surface 232, a groove 234, and a holding member 240. At least a portion of the ring member 230 may be cut. For example, the ring member 230 may be cut in a lengthwise direction. That is, the ring member 230 may be cut into a C shape. Accordingly, the ring member 230 may have a cut surface 232. The cut surface 232 may be formed in a direction parallel to a lengthwise section of the ring member 230. The ring member 230 may be divided based on the cut surface 232. According to an embodiment, the ring member 230 may be divided based on the cut surface 232.

A groove 234 may be formed in the ring member 230. The groove 234 may be formed in a region adjacent to a region at which the cut surface 232 is formed. According to an embodiment, a groove having a ‘U” shaped cross-section may be formed at an end of the ring member 230 with respect to the cut surface 232. In addition, with respect the cut surface 232, a groove having a ‘U”-shaped cross-section may be formed at the other end facing the end of the ring member 230. The groove formed at the end of the ring member 230 and the groove formed at the other end of the ring member 230 may be symmetrical with respect to the cut surface 232. The groove formed at the end and at the other end of a cut ring member 230 may be combined with each other to form a groove 234 according to an embodiment of the inventive concept. That is, when seen from above, at least a portion of the lengthwise sections of the groove 234 may overlap the cut surface 232. According to an embodiment, the groove 234 may have a rectangular parallelepiped shape having a substantially curvature. However, the inventive concept is not limited thereto, and may be modified into various shapes to be formed in the ring member 230.

The groove 234 according to an embodiment may be formed on an inner surface of the ring member 230. According to an embodiment, the groove 234 may penetrate the inner surface of the ring member 230 but may not penetrate an outer surface of the ring member 230. In addition, the groove 234 may be formed between a top end of the ring member 230 and a bottom end of the ring member 230. Specifically, the groove 234 may be formed between a top end of the inner portion and a bottom end of the inner portion of the ring member 230. In addition, the groove 234 may be formed between a top end of the outer portion and a bottom end of the outer portion of the ring member 230. That is, the top end of the groove 234 may be positioned lower than the top end of the ring member 230. In addition, the bottom end of the groove 234 may be positioned higher than the bottom end of the ring member 230.

The holding member 240 may have a shape corresponding to the shape of the groove 234. In addition, the holding member 240 may have a height corresponding to the groove 234. In addition, the holding member 240 may have a width corresponding to that of the groove 234. The holding member 240 according to an embodiment may be formed in a rectangular parallelepiped shape having a substantially curvature. However, the inventive concept is not limited thereto, and the holding member 240 may be formed in a shape corresponding to the shape of the groove 234. For example, when the cross section of the groove 234 is circular, the cross section of the holding member 240 may also be formed in a circular shape. In addition, a material of the holding member 240 may be the same as or similar to the material of the ring member 230. For example, the material of the holding member 240 may include a ceramic.

The holding member 240 according to an embodiment may be inserted into the groove 234. In addition, the holding member 240 may be taken out from the groove 234. Accordingly, the holding member 240 may be inserted into the groove 234 and positioned on the cut surface 232. The holding member 240 may be inserted into the groove 234 to maintain a position of a divided ring member 230. The holding member 240 may maintain positions of an end of the ring member 230 and the other end of the ring member 230 divided based on the cut surface 232. According to an embodiment, the holding member 240 may be inserted into the groove 234 to limit the lengthwise movement of the ring member 230 divided based on the cut surface 232.

Referring back to FIG. 2, the bottom edge electrode 250 may be formed in a ring shape. The bottom edge electrode 250 may be provided to surround an outer circumferential surface of the ring member 230 when seen from above. When seen from above, the bottom edge electrode 250 may be disposed in the edge region of the substrate W supported by the chuck 210. According to an embodiment, the bottom edge electrode 250 may be disposed below the edge region of the substrate W.

The bottom edge electrode 250 may function as a plasma source. The bottom edge electrode 250 may function as a plasma source which generates a plasma in the edge region of the substrate W by exciting a gas supplied to the treating space 102 together with a top edge electrode 510 to be described later.

The bottom edge electrode 250 is disposed to face the top edge electrode 510. The bottom edge electrode 250 may be disposed below the top edge electrode 510. The bottom edge electrode 250 may be grounded. The bottom edge electrode 250 can increase a plasma density generated in the treating space 102 by inducing a coupling of a bias power applied to the chuck 210. Accordingly, a treatment efficiency of the edge region of the substrate W may be improved.

The dielectric unit 300 may include a dielectric plate 310 and a first base 320. A bottom surface of the dielectric plate 310 may be disposed to face the top surface of the chuck 210. The top surface of the dielectric plate 310 may be formed to be stepped so that a height of a center region is relatively higher than a height of an edge region. The bottom surface of the dielectric plate 310 may be formed in a substantially flat shape.

A gas fluid channel connected to a first gas supply unit 720 to be described later may be formed in the dielectric plate 310. A discharge end of the gas fluid channel may be disposed at a position corresponding to the center region of the substrate W supported by the chuck 210 when seen from above. For example, a first gas discharged through the discharge end of the gas fluid channel may be supplied to the center region of the substrate W supported by the chuck 210.

The first base 320 may be disposed between the dielectric plate 310 and a top wall of the housing 100. A diameter of the first base 320 may gradually increase from a top to a bottom. A diameter of a top surface of the first base 320 may be relatively smaller than a diameter of a bottom surface of the dielectric plate 310. A diameter of a bottom surface of the first base 320 may correspond to a diameter of the top surface of the dielectric plate 310. The top surface of the first base 320 may have a flat shape. In addition, the bottom surface of the first base 320 may have a shape corresponding to the top surface of the dielectric plate 310.

The top electrode unit 500 may include a top edge electrode 510 and a second base 520. When seen from above, the top edge electrode 510 may be disposed to overlap the edge region of the substrate W supported by the chuck 210. The top edge electrode 510 may be disposed above the substrate W when viewed from the front.

The top edge electrode 510 may be grounded. As described above, the top edge electrode 510 is grounded and functions as a plasma source together with the bottom edge electrode 250. For example, the top edge electrode 510 may be a plasma source which generates a plasma by exciting a gas supplied to the edge region of the substrate W.

The top edge electrode 510 may be formed in a ring shape. The top edge electrode 510 may have a shape surrounding the dielectric plate 310 when seen from above. The top edge electrode 510 may be disposed to be spaced apart from the dielectric plate 310 by a predetermined distance. A separation space may be formed between the top edge electrode 510 and the dielectric plate 310. The separation space may function as a channel through which the gas flows. For example, the separation space may function as a part of a gas channel through which the second gas supplied from the second gas supply unit 740 to be described later flows. A discharge end of the separation space may be disposed at a position corresponding to the edge region of the substrate W supported by the chuck 210 when seen from above. For example, a gas discharged through the discharge end of the separation space may be supplied to the edge region of the substrate W supported by the chuck 210.

The second base 520 may be disposed above the chuck 210. The second base 520 may fix a position of the top edge electrode 510. The second base 520 may be disposed between the top edge electrode 510 and the top wall of the housing 100. The second base 520 may have a ring shape. The second base 520 may be disposed to be spaced apart from the first base 320. The second base 520 may be spaced apart from the first base 320 to form a separation space. The separation space may function as a channel through which a gas flows. For example, the separation space may function as a part of a gas channel through which the second gas supplied from the second gas supply unit 740 to be described later flows.

A separation space formed by combining the top edge electrode 510 and the dielectric plate 310 and a separation space formed by combining the second base 520 and the first base 320 may fluidly communicate with each other to function as a gas channel. The second gas supplied from the second gas supply unit 740 may be supplied to the edge region of the substrate W through the gas channel.

The gas supply unit 700 supplies a process gas to the treating space 102. The gas supply unit 700 may include a first gas supply unit 720 and a second gas supply unit 740.

The first gas supply unit 720 may supply the first gas to the treating space 102. For example, the first gas may be an inert gas including a nitrogen. The first gas supply unit 720 may supply the first gas to the center region of the substrate W supported by the chuck 210. The first gas supply unit 720 may include a first gas supply source 722, a first gas supply line 724, and a first valve 726.

The first gas supply source 722 may store the first gas. An end of the first gas supply line 724 may be connected to the first gas supply source 722, and the other end thereof may be connected to a fluid channel formed in the dielectric plate 310. The first valve 726 is installed in the first gas supply line 724. The first valve 726 may be an on/off valve or a flow rate control valve. The first gas may be supplied to the center region of the substrate W through the fluid channel formed in the dielectric plate 310.

The second gas supply unit 740 supplies the second gas to the treating space 102. The second gas supply unit 740 may include a second gas supply source 742, a second gas supply line 744, and a second valve 746.

The second gas supply source 742 may store the second gas. According to an embodiment, the second gas may be a gas excited in a plasma state. An end of the second gas supply line 744 may be connected to the second gas supply source 742, and the other end thereof may be connected to the gas channel described above. Accordingly, the second gas supply line 744 may supply the second gas to the gas channel. The second valve 746 is installed in the second gas supply line 744. The second valve 746 may be provided as an on/off valve or a flow control valve. As described above, the second gas can be supplied to the edge region of the substrate W through a gas channel formed by a combination of the top edge electrode 510, the dielectric plate 310, the second base 520, and the first base 320.

In the embodiment described above, the chuck 210 moves in a vertical direction and positions of the dielectric plate 310 and the top edge electrode 510 are fixed, but the inventive concept is not limited thereto. For example, a position of the chuck 210 may be fixed, and the dielectric plate 310 may be configured to be movable in the vertical direction. In addition, both the chuck 210 and the dielectric plate 310 may be configured to be movable in the vertical direction.

In addition, in the above embodiment, it was described as an example that the bottom edge electrode 250 and the top edge electrode 510 are grounded, respectively, but the inventive concept is not limited to this. Any one of the bottom edge electrode 250 and the top edge electrode 510 may be grounded, and the other may be connected to an RF power source. In addition, both the bottom edge electrode 250 and the top edge electrode 510 may be connected to the RF power source.

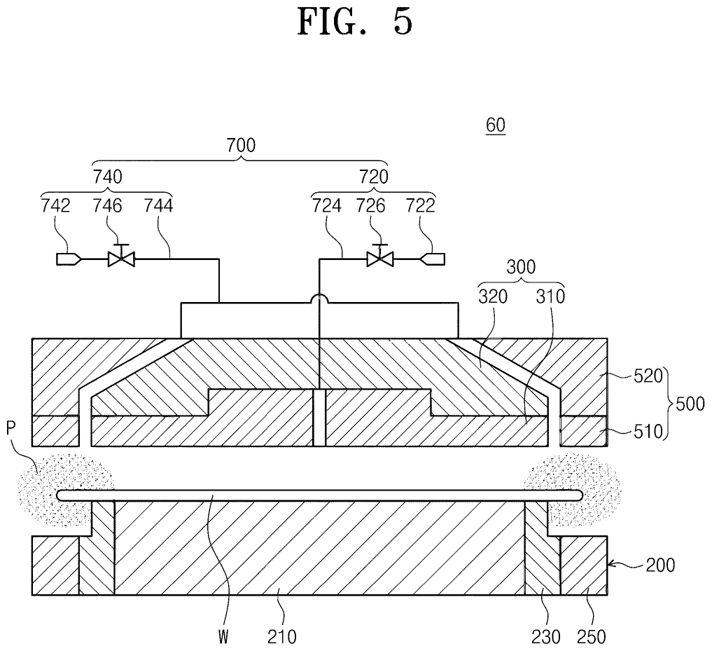

FIG. 5 schematically illustrates the process chamber according to an embodiment of FIG. 2 performing a plasma treatment process.

Referring to FIG. 5, the process chamber 60 according to an embodiment of the inventive concept may process the edge region of the substrate W by generating the plasma P in the edge region of the substrate W. For example, the process chamber 60 may perform a bevel etch process of treating the edge region of the substrate W.

When the substrate W is mounted on the top surface of the chuck 210, the gas supply unit 700 supplies the gas to the center region of the substrate W and the edge region of the substrate W. The second gas supplied through the gas channel may be excited in the plasma P state to treat the edge region of the substrate W. For example, the film formed in the edge region of the substrate W may be etched by the plasma P.

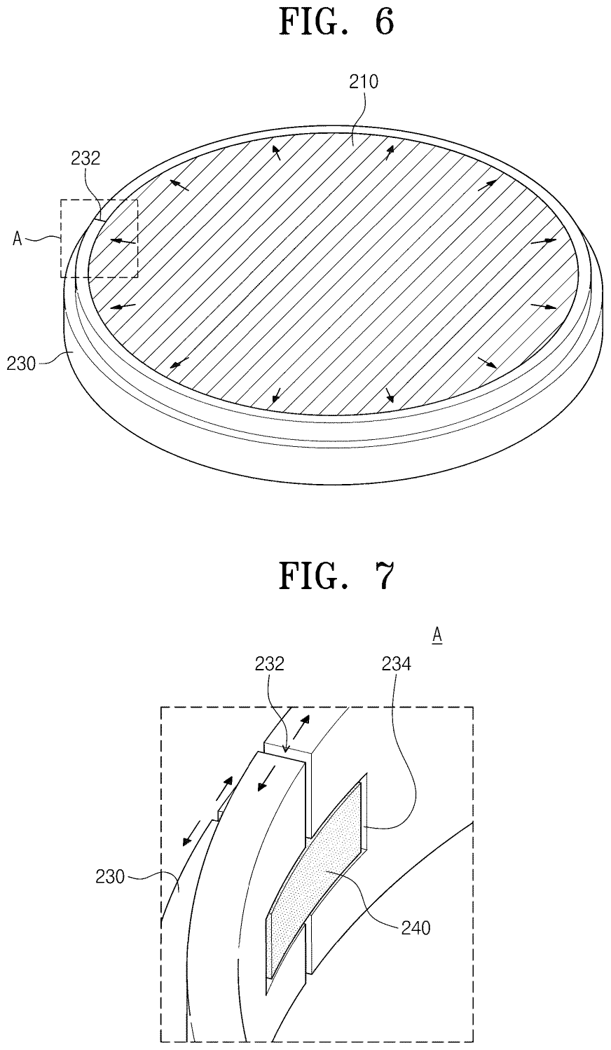

FIG. 6 is a perspective view schematically illustrating a chuck thermally expanding when a plasma treatment process is performed in the process chamber according to an embodiment of FIG. 2. FIG. 7 schematically illustrates an enlarged view of a portion A of FIG. 6.

When the plasma treatment process is performed in the process chamber 60 according to an embodiment of the inventive concept, the chuck 210 may thermally expand. Specifically, when the plasma is generated in the treating space 102, a temperature of the treating space 102 increases. That is, while treating the substrate using the plasma, a high-temperature atmosphere is created in the treating space 102. If the temperature of the treating space 102 increases, the chuck 210 may thermally expand as shown in FIG. 6. In addition, the ring member 230 may be thermally expanded.

As described above, the material of the chuck 210 may include an aluminum, and the material of the ring member 230 may include a ceramic. That is, since the chuck 210 is made of a metal material, it expands relatively more by a heat compared to the ring member 230. According to an embodiment of the inventive concept, the chuck 210 and the ring member 230 share their center to generate a uniform and precise plasma in the edge region of the substrate, and an outer side of the chuck 210 and an inner side of the ring member 230 are positioned in contact with each other. In this structure, if the chuck 210 expands relatively more by the heat than the ring member 230, the chuck 210 may damage the ring member 230. For example, if the plasma is generated in the treating space 102 and a high-temperature atmosphere is created in the treating space 102, the chuck 210 can thermally expand in a radial direction to transmit a force due to the thermal expansion to the ring member 230. In addition, if the heater 212 positioned inside the chuck 210 generates a heat when treating the substrate, a temperature of the chuck 210 increases, so the chuck 210 can thermally expand in the radial direction.

The ring member 230 according to an embodiment of the inventive concept includes a cut surface 232. By forming the cut surface 232 on the ring member 230, a position of the ring member 230 may be slightly changed in the radial direction. Accordingly, the ring member 230 may be changed in the radial direction in response to the force transmitted by the expansion of the chuck 210 in the radial direction. That is, by the cut surface 232 formed on the ring member 230, the force transmitted from the chuck 210 may minimize a damage to the ring member 230. That is, according to an embodiment of the inventive concept, even if a force due to the thermal expansion is transmitted from the chuck 210, such a force may be alleviated. In addition, since the force applied between the ring member 230 and the chuck 210 is relieved, a damage to the outer surface of the chuck 210 by the ring member 230 can be minimized.

In addition, since the ring member 230 preemptively relieves the force transmitted from the chuck 210, a damage that the ring member 230 can subsequently apply to the bottom edge electrode 250 can be blocked in advance. That is, the ring member 230 according to an embodiment may serve as a so-called buffer for relieving the force due to the thermal expansion. Accordingly, it is possible to generate a uniform and precise plasma in the edge region of the substrate.

In addition, according to an embodiment of the inventive concept, the holding member 240 may be cut to maintain the position of a divided ring member 230. Specifically, the holding member 240 may be inserted into the groove 234 to limit a lengthwise movement of the divided ring member 230 with respect to the cut surface 232. Even if the chuck 210 thermally expands and pushes the ring member 230 in the radial direction, it can suppress a phenomenon in which divided parts of the ring member 230 are twisted in the lengthwise direction by the holding member 240. Accordingly, since a height of the top surface of the ring member 230 does not change, a step is not generated in the ring member 230 and plasma may be uniformly generated in the edge region of the substrate.

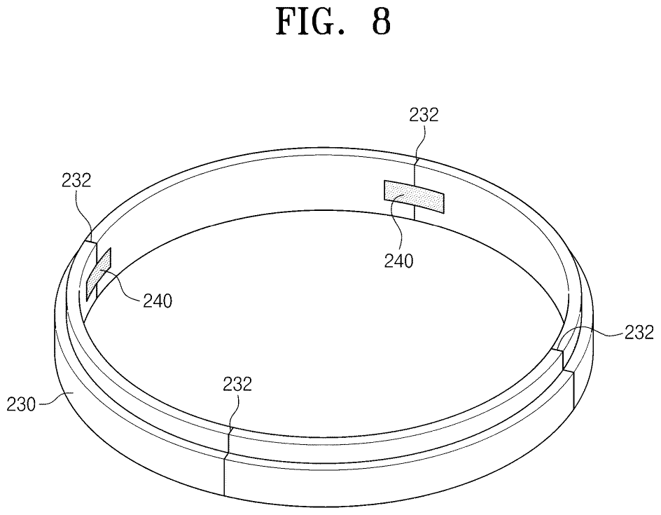

FIG. 8 is a perspective view illustrating the ring member according to another embodiment of FIG. 2. Hereinafter, the ring member according to another embodiment of the inventive concept will be described with reference to FIG. 8. Except for the case of additional description below, most of the configuration of the ring member is the same or similar to the configuration of the ring member described above, and a description of the overlapping contents will be omitted.

Referring to FIG. 8, a plurality of cut surfaces 232 may be formed in the ring member 230 according to an embodiment of the inventive concept. For example, as illustrated in FIG. 8, four cut surfaces 232 may be formed in the ring member 230. Accordingly, the ring member 230 may be divided into four parts. However, the inventive concept is not limited thereto, and the plurality of cut surfaces 232 (two or more natural numbers) may be formed in the ring member 230.

In addition, a plurality of grooves 234 may be formed in the ring member 230. The plurality of grooves 234 may be provided in the same number as the cut surface 232 formed in the ring member 230. Each of the plurality of grooves 234 may be formed at a position corresponding to each of the plurality of cut surfaces 232. In addition, a plurality of holding members 240 may be inserted into each of the plurality of grooves 234.

If the temperature of the treating space 102 is made very high, or if the heater 212 positioned within the chuck 210 generates a heat at a high temperature when treating the substrate, an expansion by a heat of the chuck 210 further increases. Since the ring member 230 according to another embodiment of the inventive concept described above includes the plurality of cut surfaces 232, the plurality of grooves 234, and the plurality of holding members 240, the position of the ring member 230 can be changed more smoothly in the radial direction. Accordingly, despite an expansion rate due to the high heat of the chuck 210, a damage applied to the ring member 230 may be minimized. In addition, even if the chuck 210 according to an embodiment includes a material with a greater thermal expansion rate than an aluminum, the damage to the ring member 230 due to the thermal expansion of the chuck 210 can be minimized.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a housing having a treating space;
a support unit configured to support a substate within the treating space; and
a plasma source for generating a plasma by exciting a gas supplied to the treating space, and
wherein the support unit includes:
a chuck having the substrate mounted to a top surface thereof; and
a ring member in a ring shape surrounding an outer side of the chuck, and
the ring member includes a cut surface which divides the ring member and a holding member positioned at the cut surface which holds a position of the ring member which is divided by the cut surface.

2. The substrate treating apparatus of claim 1, wherein a groove at which the holding member is inserted is formed at the ring member.

3. The substrate treating apparatus of claim 2, wherein the groove is formed at an inner side of the ring member, and
a top end of the groove is positioned lower than a top end of the ring member, and a bottom end of the groove is positioned higher than a bottom end of the ring member.

4. The substrate treating apparatus of claim 2, wherein the ring member is divided with respect to the cut surface, and
the holding member is inserted in the groove to limit a movement in a lengthwise direction of each divided ring member.

5. The substrate treating apparatus of claim 1, wherein the cut surface is formed in a horizontal direction to the cut surface of the ring member.

6. The substrate treating apparatus of claim 1, wherein at the ring member, a plurality of cut surfaces are formed along a circumferential direction of the ring member, and
a plurality of holding members are each positioned at each of the plurality of cut surfaces.

7. The substrate treating apparatus of claim 1, further comprising:
a dielectric plate positioned to face a top surface of the substrate supported on the support unit; and
a gas supply unit configured to supply a gas to an edge region of the substrate, and
wherein the plasma source includes:
a top edge electrode positioned above the edge region; and
a bottom edge electrode positioned below the edge region.

8. The substrate treating apparatus of claim 7, wherein the bottom edge electrode is formed in a ring shape, and surrounds an outer side of the ring member.

9. The substrate treating apparatus of claim 1, wherein the chuck and the ring member share a same center, and an inner side of the ring member contacts the outer side of the chuck.

10. The substrate treating apparatus of claim 1, wherein the chuck and the ring member have a different thermal expansion rate from one another.

11. A support unit for supporting a substrate comprising:
a chuck supporting the substrate on a top surface;
a ring member in a ring shape surrounding an outer circumference of the chuck; and
an edge electrode formed in a ring shape surrounding an outer circumference of the ring member, and which is positioned at an edge region of the substrate supported on the chuck to generate a plasma at the edge region, and
wherein the ring member includes a cut surface dividing the ring member and a holding member positioned at the cut surface which holds a position of the ring member which is divided by the cut surface.

12. The support unit of claim 11, wherein the chuck and the ring member share a same center, and an inner side surface of the ring member contact an outer side of the chuck.

13. The support unit of claim 12, wherein a thermal expansion rate of the chuck and a thermal expansion rate of the ring member are different from one another.

14. The support unit of claim 13, wherein the thermal expansion rate of the chuck is higher than the thermal expansion rate of the ring member.

15. The support unit of claim 11, wherein a groove at which the holding member is inserted is formed at the ring member,
the groove is formed at an inner side of the ring member, and
a top end of the groove is positioned lower than a top end of the ring member, and a bottom end of the groove is positioned higher than a bottom end of the ring member.

16. The support unit of claim 15, wherein the ring member is divided with respect to the cut surface, and
the holding member is inserted in the groove to limit a movement in a lengthwise direction of each divided ring member.

17. The support unit of claim 16, wherein at the ring member, a plurality of cut surfaces are formed along a circumferential direction of the ring member, and
a plurality of holding members are each positioned at each of the plurality of cut surfaces.

18. A substrate treating apparatus comprising:
a housing having a treating space;
a support unit configured to support a substate within the treating space;
a dielectric plate positioned to face a top surface of a substrate supported on the support unit;
a gas supply unit configured to supply a gas to an edge region of the substrate;
a top edge electrode positioned above the edge region; and
a bottom edge electrode positioned below the edge region, and
wherein the support unit includes:
a chuck having the substrate mounted to a top surface thereof; and
a ring member in a ring shape surrounding an outer side of the chuck, and
the ring member includes:
a cut surface which divides the ring member;
a groove which is formed at a position corresponding to the cut surface; and
a holding member inserted in the groove to limit a movement in a lengthwise direction of the ring member which is divided by the cut surface.

19. The substrate treating apparatus of claim 18, wherein the chuck and the ring member share a same center, and an inner side of the ring member contacts the outer side of the chuck, and the groove is formed at the inner side between a top end of the ring member and a bottom end of the ring member.

20. The substrate treating apparatus of claim 18, wherein the chuck and the ring member have a different thermal expansion rate from one another.
